(19) United States
(12) Patent Application Publication
(10) Pub. No.: US 2016/0239376 A1
(43) Pub. Date: Aug. 18, 2016

(54) TEST CASE CRASH RECOVERY

(71) Applicant: TEXAS INSTRUMENTS INCORPORATED, Dallas, TX (US)

(72) Inventor: Jerome Demay, Valbonne (FR)

(21) Appl. No.: 15/137,560

(22) Filed: Apr. 25, 2016

Related U.S. Application Data
(62) Division of application No. 13/585,584, filed on Aug. 14, 2012.

(30) Foreign Application Priority Data
Aug. 13, 2012 (EP) 12290271.1

(51) Int. Cl. G06F 11/07; G01R 31/30; G01R 31/28

(52) U.S. Cl. CPC G06F 11/0793; G01R 31/2851; G01R 31/3004; G06F 11/0706; G06F 11/0757; G06F 11/079

(57) ABSTRACT

A safe operating region of a complex integrated circuit may be determined by selecting an operating point for the integrated circuit (IC) at a first voltage and first frequency. A test program is executed by a central processing unit (CPU) comprised within the IC to test a portion of the IC. Communication activity between the IC and a host system is recorded to form a data log while the test program is being executed. A crash is detected by storing and examining the data log periodically, and assuming that the test program has crashed when any one of a predetermined set of crash conditions is detected during examination of the data log. The operating point may be iteratively changed and execution of the test program repeated while continuing to check for a crash until a crash is detected.

### CLAIM OF PRIORITY UNDER 35 U.S.C. 119(e)

This application is a Divisional of prior application Ser. No. 13/585,584, filed Aug. 14, 2012, currently pending;

And claims priority to and incorporates by reference European Patent Office application number EP 12290271.1, filed Aug. 13, 2012, entitled “Test Case Crash Recovery.”

### FIELD OF THE INVENTION

This invention generally relates to testing and evaluation of a complex integrated circuit, and in particular to determining the limits of voltage and frequency operation in a time efficient manner.

### BACKGROUND OF THE INVENTION

System on Chip (SoC) is a concept that has been around for a long time; the basic approach is to integrate more and more functionality into a given device. This integration can take the form of hardware and solution software. Performance gains are traditionally achieved by increased clock rates and by using more advanced processer nodes. Many SoC designs pair a digital signal processor (DSP) with a reduced instruction set computing (RISC) processor to target specific applications.

When a new SoC is designed, it must be characterized to determine over what range of voltages and frequencies the various processors, memories and other logic modules on the SoC will operate correctly. This is generally done by executing various test programs that exercise all, or a significant portion of, the various data paths, memories, and control logic within the SoC at a selected operating point of voltage, frequency, and temperature. If the test suite crashes, or if it detects an erroneous result, then it may be assumed that the current operating point is outside of the safe operating region. Similarly, if the test suite is completed successfully, then it may be assumed that the current operating point is within the safe operating region. After each test either passes or fails, the voltage, frequency, and/or temperature may be changed and the test repeated. This process is repeated until a safe operating region is identified.

### BRIEF DESCRIPTION OF THE DRAWINGS

Particular embodiments in accordance with the invention will now be described, by way of example only, and with reference to the accompanying drawings:

FIG. 1 is a block diagram of a test bed that includes an embodiment of the invention;

FIG. 2 is a flow diagram illustrating a test flow for determining a safe operation region;

FIG. 3 is a flow diagram illustrating detection of a crash based on analysis of a UART log file; and

FIG. 4 is a plot illustrating a safe operating region

FIG. 5 a functional block diagram of a system on chip (SoC);

Other features of the present embodiments will be apparent from the accompanying drawings and from the detailed description that follows.

### DETAILED DESCRIPTION OF EMBODIMENTS OF THE INVENTION

Specific embodiments of the invention will now be described in detail with reference to the accompanying figures. Like elements in the various figures are denoted by like reference numerals for consistency. In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

When a new SoC (system on a chip) is designed, it must be characterized to determine over what range of voltages and frequencies the various processors, memories and other logic modules on the SoC will operate correctly. A host test system may be used to instruct the SoC to execute a suite of test programs that exercise all, or a significant portion of, the various data paths, memories, and control logic within the SoC at a selected operating point of voltage, frequency, and temperature. If the test suite crashes, or if it detects an erroneous result, then it may be assumed that the current operating point is outside of the safe operating region. Similarly, if the test suite is completed successfully, then it may be assumed that the current operating point is within the safe operating region. After each test either passes or fails, the voltage, frequency, and/or temperature may be changed and the test repeated. This process is repeated until a safe operating region is identified.

A crash may occur at any time during execution of a test program. Frequently, a crash may occur without providing any indication to the host test system that is controlling the characterization process. As a result, the host test system must determine if the SoC has crashed when it does not receive status updates from the SoC. The host test system may wait for a defined timeout period of time after receiving a last status update; however, the timeout period must be long enough to cover the worst case response time in the suite of test programs. As a result, the timeout period may need to be long enough that the total testing time required to completely determine the safe operating region is excessive.

A more time efficient crash detection process will be described herein that allows crashes to be detected without waiting for a defined timeout period. This improved crash detection process is time optimized to allow rapid detection of a crash without prematurely stopping a test program that is merely responding slowly.

An embodiment of the invention may include a host test system that is coupled to a SoC that is being characterized. The coupling may be accomplished via a communication channel that is established between a communication port on the host test system and a communication port on the SoC. For example, a universal asynchronous receiver and transmitter (UART) may be included within the host test system and within the SoC to provide a serial communication channel. Using this channel, the host test system may instruct a processor within the SoC to execute a test program. During execution of the test program, another process being executed by a processor on the SoC may send status update messages back to the host test system via the communication channel. The stream of status update messages from the SoC may be collected in a log file by a process being executed on the host test system. This log file will be referred to herein as the UART log file. In other embodiments, a communication interface that is not a UART may be used; for example, it may be a parallel communication channel, it may be based on wired or wireless technology, etc. In all embodiments, the generic term “UART log file” may be used to refer to a set status data that is collected over a period of time from the SoC being tested.

In order to efficiently detect and recover from a crash, the host test system needs to handle crash scenarios, such as the following: an empty UART log file, which may have been caused by a setup error; an oversize UART log file, which may be caused when unknown and unpredictable characters are transmitted by the SoC when it crashes; detection of a known key word that may be transmitted when the test program detects an error but does not crash; and a frozen UART log file in which no new information is received. Key word detection may occur when a test program is exercising a portion of the logic within the SoC and the test fails; however, the test program itself is still being executed and it may cause a keyword, such as “abort”, or some other predefined message, to be transmitted to the host test system.

Another embodiment may be used during production testing of large quantities of the SoC. During production testing, it may not be economical to provide a communication link to the SoC being tested. However, the production test-bed may couple to a memory circuit on the SoC via connection points on the SoC package, such as a ball grid array. In this case, the host test system may monitor status messages written into a region of the memory by a test suite being executed by a processor within the SoC. The data written into the memory region may be used to create a “UART log file” for this embodiment.

Due to exponential increases in computation and communication capabilities while being constrained by battery energy storage, maximum surface and internal temperature of portable devices, designers are requesting more and more complex power saving techniques. Switching power dissipated by a CMOS device is P=CV²F with C=load capacitance, V=supply voltage and F=switching frequency. Lowering the supply voltage reduces the power dissipated and consequently battery energy is saved and the control of internal temperature of portable devices is easier. Therefore, in many applications it is advantageous to identify the lowest voltage at which the device will reliably operate.

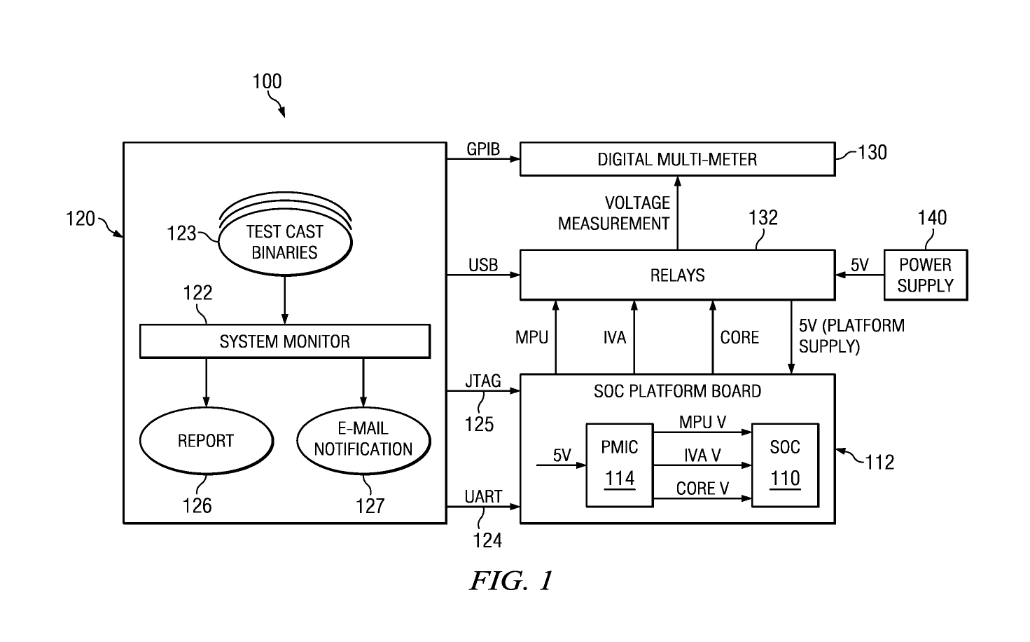

FIG. 1 is a block diagram of a test bed 100 that includes an embodiment of the invention. SoC 110 is the target device that is to be characterized. It may be mounted in a connector that is coupled to platform circuit board 112 to provide cable connections to other parts of the test bed. Circuit board 112 may include other components that are used by the test bed, or it may be essentially empty except for the socket for SoC 110. In this embodiment, power management integrated circuit (PMIC) 114 is included and is coupled to receive power provided by power supply 140 and to supply various voltages required by SoC 110.

Test host system 120 may be personal computer, a laptop computer, or another type of processing system that includes a processor and programs that may be executed by the processor to embody a system monitor 122. System monitor 122 has access to test case programs 123 that may be downloaded to SoC 110 via JTAG communication channel 125. Code Composer Studio (CCS) is a well known in-circuit emulator that is available from Texas Instruments, Inc. and is included in this embodiment as system monitor 122

JTAG (Joint Test Action Group) buss 125 also provides a communication channel between SoC 110 and system monitor 122. JTAG is the common name for what was later standardized as the IEEE 1149.1 It is a well known scheme that includes a standardized test access port and boundary scan logic within SoC 110. JTAG is typically used as the primary means of accessing sub-blocks of integrated circuits, making it a useful mechanism for debugging embedded systems which may not support any other debug-capable communications channel. On most systems, JTAG-based debugging is available from the very first instruction after CPU reset, letting it support development of early boot software which runs before anything is set up. A so-called in-circuit emulator such CCS (or more correctly, “JTAG adapter”) uses JTAG as the transport mechanism to access on-chip debug modules inside the target CPU. Those modules let software developers debug the software of an embedded system directly at the machine instruction level when needed, or (more typically) in terms of high level language source code. Besides debugging, another application of JTAG is allowing a host test system to transfer data into internal volatile device memory.

System monitor 122 may create reports 126 during and/or at the end of the characterization process of SoC 110. Email notifications 127 may also be initiated by system monitor 122 to update an operator that may be at a remote location.

Power supply 140 provides a 5v supply voltage that is provided to SoC platform board 112 for use by SoC 110. The power supply 140 allows a proper recovery of the SOC platform board 112 by being switched OFF and then ON again from the sytem monitor 122 once a crash or a test error has been detected. In other embodiments, a different supply voltage may be provided, based on the requirements of the SoC being tested. In this embodiment, PMIC 114 receives the 5V and can provide a voltage from 0.5V to 1.8V in response to commands received over the UART channel. However, in this example, SoC 110 works in the range from 0.7V to 1.4V. In this embodiment, SoC 110 requires three supply voltages, one for an on-chip microprocessor (MPU), one for an image, video, and audio accelerator (IVA), and one for the rest of the core logic (CORE). In this example, operating frequency ranges for SoC 110 are 400 MHz to 1.7 GHz for MPU (Micro-processor Unit) sub-system, 200 MHz to 500 MHz for IVA (Image, Video, and Audio) sub-system and 200 MHz to 450 MHz for Memory sub-system.

Digital multi-meter 130 is coupled to a relay module 132 that allows each of the three voltages produced by PMIC 114 to be selected and monitored during a test. Multi-meter 130 is coupled to host test system 120 via a GPIB cable (General Purpose Interface Bus), which is also known as IEEE-488, a short-range digital communications bus specification used commonly in test systems. Relay module 132 is controlled by the system monitor 122 via a USB (universal synchronous bus) connection, another well known interface standard.

A UART on SoC 110 is managed by a UART driver which is part of common environment software that is included on the SoC. This allows the UART to be used independent of a Test case/pattern that is being executed on the SoC. The common environment software is used to initialize the SoC by setting voltages, enabling clocks, wakeup some IP such CPUs, UARTs, etc. A UART within host test system 120 is managed by a communication package that is capable of creating a log file to preserve all information transmitted via UART communication channel 124. In this embodiment, a communication package known as Tera Term is used, which is an open source free software terminal emulator supporting UTF-8 (UCS Transformation Format-8 bit) protocol. It may also support SSH1 (Secure Shell 1) and/or SSH2 (Secure Shell 2) protocol.

While a test is being performed, two levels of communication may occur. The first level of communication is independent of the Test case/pattern. The system monitor may send some commands to SoC platform 112 to change voltages, clock frequencies and other specific configurations to establish a particular operation point. Then SoC platform 112 answers to the system monitor to indicate that if it was successful or not in performing the requested changes. If everything is OK, then the system monitor requests to SoC to launch/execute a specified Test case/pattern. Otherwise, a retry is performed and after a certain number of attempts, the test may be indicated as failed.

The second level of communication is test case/pattern dependent. SoC 110 sends information to the system monitor via UART channel 124. This information may include statements about what's going on inside the test itself, such as where it is, if everything is ok, etc., information that is specific to the test case/pattern. When each test case/pattern ends, if the test case/pattern can be executed till its end without crashing, its status is reported by a known keyword as either “test case failed” or “test case passed”, for example.

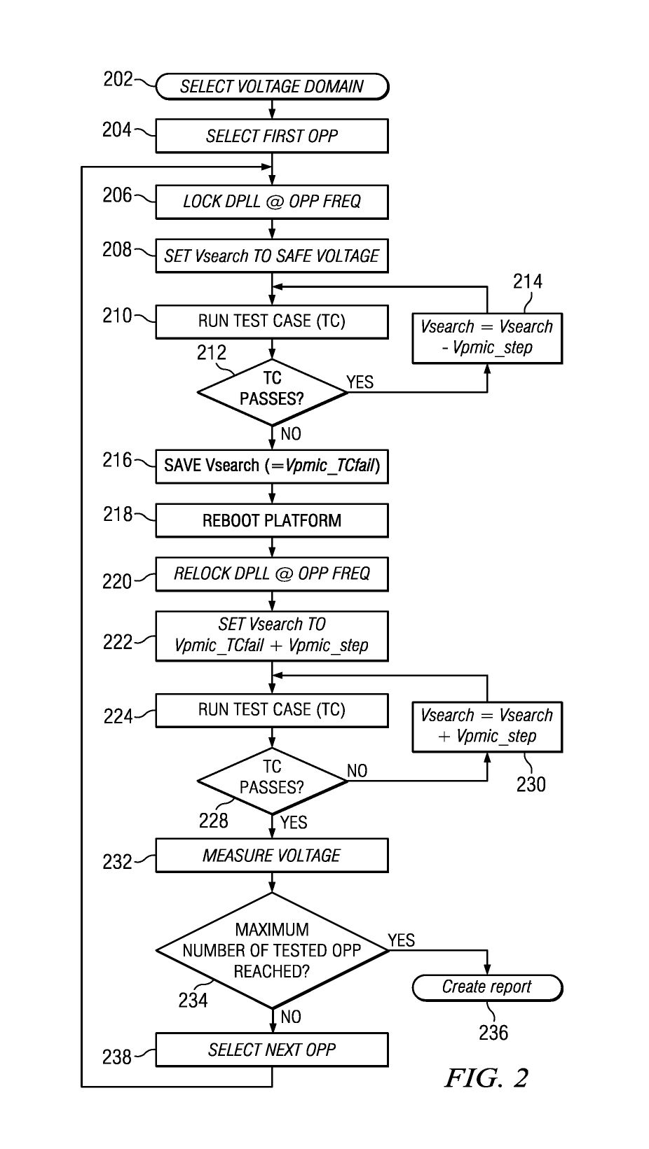

FIG. 2 is a flow diagram illustrating a test flow for determining a safe operation region that utilizes the procedure for detecting program crashes described herein. Since the SoC of the current embodiment has three voltage domains (MPU, IVA, and CORE) as described earlier, one of the domains is selected 202 for characterization. The test case program 123 is able to find and run one by one all the test case programs 123 by providing only the location path—no need to provide neither the names nor a list of the test case programs 123 to be loaded and to be run. Each test case program 123 is also accompanied with a text file which includes some environment variables used by System monitor 122. Such environment variables indicate to the System monitor 122 which UART port number to use, which voltage domain to select 202, etc. An initial operating point is selected 204. As mentioned earlier, an operating point may include voltage, frequency, and temperature, for example. Once the operating point is selected, a command is sent from the system monitor to cause the digital phase locked loop (DPLL) to be locked 206 to the selected frequency. A command is also sent to relay module 132 to monitor the selected voltage domain. The voltage provided to the selected domain is then set 208 to an initial voltage search value that should be well within the safe operation region by sending a command from system monitor 122 to PMIC 114 to generate the specified voltage. System monitor 122 may read digital multi-meter 130 to verify that a selected voltage has been generated, and send additional PMIC commands if needed.

System monitor 122 then selects an appropriate one of test case programs 123 and downloads it to SoC 110 via JTAG interface 125. Once the test case has been downloaded, system monitor 122 sends a command to SoC 110 via JTAG UART channel 124 that causes the test case to be executed by a processor within SoC 110. While the test case is being executed, status information is sent back to system monitor 122 via UART channel 124, as described earlier. System monitor 122 then analyzes the UART log file to determine 212 if the test case completes successfully, detects an error, or crashes. Each time the test case is completed successfully, the domain search voltage is reduced 214 by a step value that is communicated to PMIC 114 and the test is then restarted 210. This iteration loop continues until a crash or a failure is detected 212.

Once a crash is detected, the current search voltage value is saved 216 and identified as a failure value. A proper recovery of the SOC platform board 112 is then performed assisted by the power supply 140 by being switched OFF and then ON again under control by the system monitor 122. The SoC is then rebooted by sending commands from system monitor to SoC 110 via JTAG 125 interface. After rebooting, the frequency is again locked 220 in the DPLL. The search voltage for the selected domain is then set 222 to a value that is a step above the last failure voltage. The test case is then run 224 by sending commands to SoC 110 as described above and the UART log is again monitored to detect 228 success or failure of the test case execution. Each time the test case fails 228, a proper recovery of the SOC platform board 112 is performed, the SoC is rebooted and the domain search voltage is increased 230 by a step value that is communicated to PMIC 114 and the test is then restarted 224. This iteration loop continues until the test case is performed correctly 228. The domain voltage is then measured 232 and saved as the final minimum voltage value for correct operation at the current frequency value. In this manner, an initial failure voltage is determined for a downward ramping of the voltage and then the final minimum operating voltage is determined for an upward ramping of the voltage.

This entire iteration process is repeated 234 with a new operation point 238 until the last operating point is completed. At this point, a report may be generated 236 that documents the safe operation region based on the measured voltages 232 over a range of frequencies.

A complete characterization of SoC 110 may take several hours, depending on the complexity and execution time of the test case program suite, crash detection time, and the time to reboot after each crash. During this time, system monitor 122 may send email notifications 127 to the technician that is overseeing the characterization process to provide updates on the progress of the characterization process.

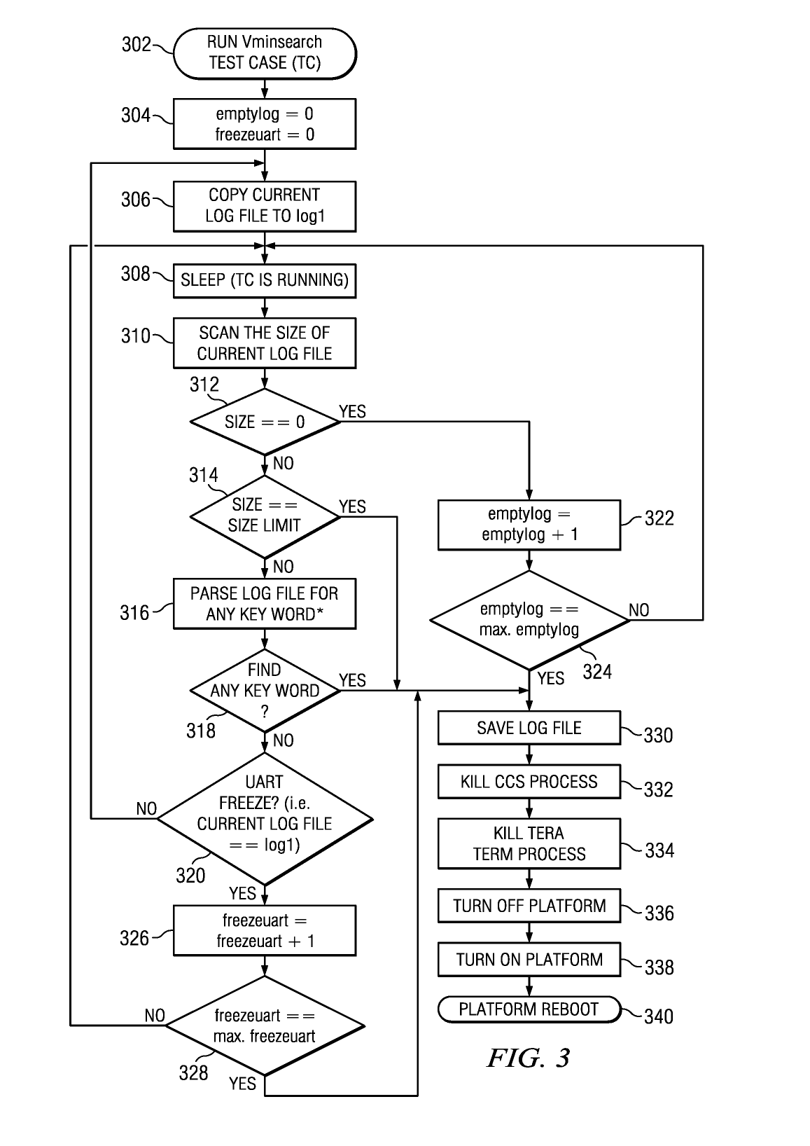

FIG. 3 is a flow diagram illustrating detection of a crash based on analysis the UART log file that is created during the test process described with regard to FIG. 2. Each time a test case is run 302, the crash detection process begins. Running a test case 302 refers to both 210 and 224 in FIG. 2. Two variables are initialized 304: emptylog is set to “0” and freezeuart is set to “0”. When the test case is started, the UART log file is cleared, so that the initial UART log file length is zero. The content of the current log file is then copied 306 to a file referred to as “log 1” for use later. The crash detection process then waits 308 for a specified sleep time period while the test case continues to run. The sleep period, which is always short to optimize crash time detection, may be a default value, or in some embodiments an operator input to system monitor 122 may be used to specify the sleep period.

At the end of the sleep period, the crash detection process resumes and scans 310 the size of the current UART log file. If the UART log file length is still equal to zero 312, then the emptylog variable is incremented 322 by an increment value, typically one. If the value of the emptylog variable exceeds 324 a maximum emptylog value, then it is assumed a crash has occurred and a crash recovery process is initiated 330. If the value of the emptylog variable is less than 324 the maximum emptylog value, then the crash detection process returns to sleep 308. The maximum emptylog value may be a default value, or in some embodiments an operator input to system monitor 122 may be used to specify the maximum emptylog value. An empty UART log file may have been caused by a setup error or some other problem that prevented the test case from running.

If the UART log file length is not equal to zero 312, then the size of the UART log file is compared 314 to a UART log file size limit value. If the size of the UART log is equal to or greater than the limit value, then it is assumed a crash has occurred and a crash recovery process is initiated 330. An oversize UART log file may be caused when unknown and unpredictable characters are transmitted by the SoC when it crashes.

If the size of the UART log is not equal to or greater than the limit value 314, then the UART log file is parsed 316 for specific known key words. In this embodiment, the known keywords are: “abort,” “minimum SMPS voltage reached,” and “test case failed.” A key word will appear in the UART log file when the test case detects a failure in the hardware that it is testing but the hardware fault does not cause execution of the test case program to crash. Other embodiments may have more, fewer, or different key words, depending on the test case programs being used. If a key word is detected 318, then it is assumed a failure of some sort has occurred and a crash recovery process is initiated 330.

If no key word is detected 318, then the current UART log file is compared 320 to the previous contents of the UART log file that were stored 306 in the file named log 1. If they are the same, then the freezeuart variable is incremented 326 by an increment value, typically one. If the value of the freezeuart variable exceeds 328 a maximum freezeuart value, then it is assumed a crash has occurred and a crash recovery process is initiated 330. If the value of the freezeuart variable is less than 328 the maximum freezeuart value, then the crash detection process returns to sleep 308. The maximum freezeuart value may be a default value, or in some embodiments an operator input to system monitor 122 may be used to specify the maximum freezeuart value.

Once a crash condition has been assumed, based on the tests described above, the current log file is saved 330. The saved contents may be analyzed at a later time. Any processes on system monitor 122 that may be waiting on a response from the test case are then killed 332. The terminal emulation program that is monitoring the UART on the system monitor is killed 334. SoC platform 112 is then turned off 336 so that SoC 110 is reset. After the SoC has been reset and all pending processes killed, SoC platform 112 is then turned on 338. A full reboot of SoC 110 is then performed 340 by system monitor 122 using the JTAG interface as was described above.

After the SoC has completed the reboot, then the system monitor resumes test case execution at either 212 or 228 in FIG. 2. Note, reboot operation 218 is not an additional reboot; it is just illustrated for clarity.

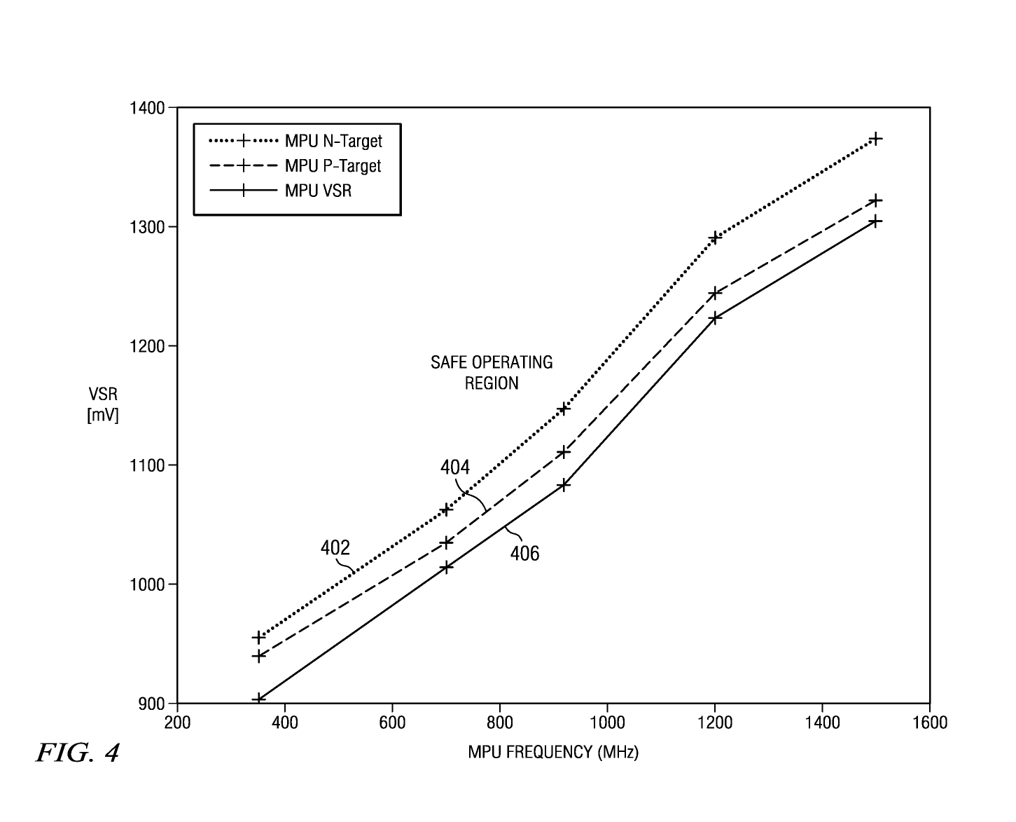

FIG. 4 is a plot of voltage versus operating frequency illustrating a safe operating region that may be efficiently determined using the process described above. In this example, plot 402 represents a design target for N-MOS transistors on MPU voltage domain that is within SoC 110, plot 404 represents a design target for P-MOS transistors on MPU voltage domain that is within SoC 110, and plot 406 represent the actual safe region voltage (VSR) that was determined during a characterization process as described above.

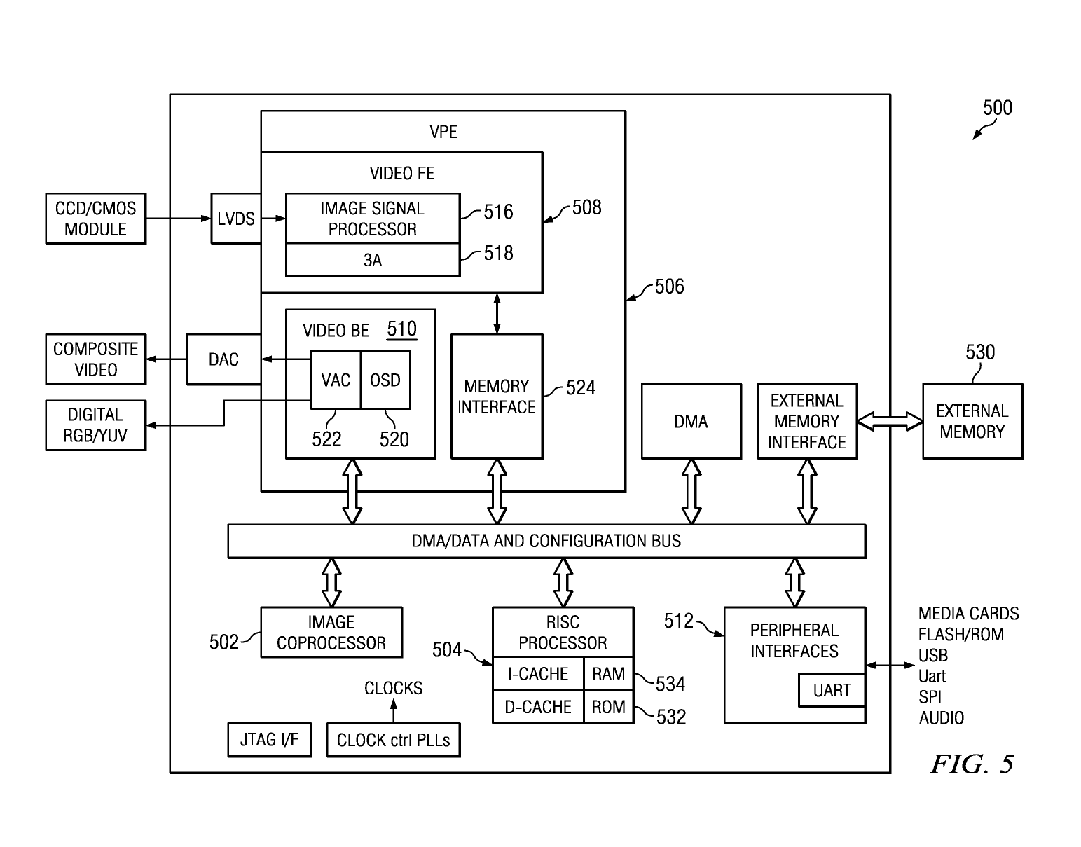

FIG. 5 is a functional block diagram of an exemplary SoC 500 that may be characterized as described herein, that includes, among other components, a DSP-based image coprocessor (ICP) 502, a RISC processor 504, and a video processing engine (VPE) 506. The RISC processor 504 may be any suitably configured RISC processor. The VPE 506 includes a configurable video processing front-end (Video FE) 508 input interface used for video capture from imaging peripherals such as image sensors, video decoders, etc., a configurable video processing back-end (Video BE) 510 output interface used for display devices such as SDTV displays, digital LCD panels, HDTV video encoders, etc, and memory interface 524 shared by the Video FE 508 and the Video BE 510. The digital system also includes peripheral interfaces 512 for various peripherals that may include a multi-media card, an audio serial port, a Universal Serial Bus (USB) controller, a UART serial port interface, etc. SoC 500 may be one of a family of OMAP (Open Media Access Platform) devices available from Texas Instruments Inc., for example.

The Video FE 508 includes an image signal processor (ISP) 516, and a 3A statistic generator (3A) 518. The ISP 516 provides an interface to image sensors and digital video sources. More specifically, the ISP 516 may accept raw image/video data from a sensor (CMOS or CCD) and can accept YUV video data in numerous formats. The ISP 516 also includes a parameterized image processing module with functionality to generate image data in a color format (e.g., RGB) from raw CCD/CMOS data. The ISP 516 is customizable for each sensor type and supports video frame rates for preview displays of captured digital images and for video recording modes. The ISP 516 also includes, among other functionality, an image resizer, statistics collection functionality, and a boundary signal calculator. The 3A module 518 includes functionality to support control loops for auto focus, auto white balance, and auto exposure by collecting metrics on the raw image data from the ISP 516 or external memory.

The Video BE 510 includes an on-screen display engine (OSD) 520 and a video analog encoder (VAC) 522. The OSD engine 520 includes functionality to manage display data in various formats for several different types of hardware display windows and it also handles gathering and blending of video data and display/bitmap data into a single display window before providing the data to the VAC 522 in YCbCr format. The VAC 522 includes functionality to take the display frame from the OSD engine 520 and format it into the desired output format and output signals required to interface to display devices. The VAC 522 may interface to composite NTSC/PAL video devices, S-Video devices, digital LCD devices, high-definition video encoders, DVI/HDMI devices, etc.

The memory interface 524 functions as the primary source and sink to modules in the Video FE 508 and the Video BE 510 that are requesting and/or transferring data to/from external memory. The memory interface 524 includes read and write buffers and arbitration logic.

The ICP 502 includes functionality to perform the computational operations required for video encoding and other processing of captured images. The video encoding standards supported may include one or more of the JPEG standards, the MPEG standards, and the H.26x standards.

Obviously, with this amount of complexity, fully testing all of the functional units, data paths, memory circuits, etc requires an extensive suite of test case programs. Generally, each major component used in a SoC such as this, has a test case program written for it. When a SoC is designed, various major components may be selected from a design library, almost like a parts catalog, and combined together with appropriate data paths and glue logic to provide a required functionality for the SoC.

Once a SoC has been designed, then all of the prewritten test cases are gathered into a test suite for that particular SoC. When the first sample SoC is fabricated, it must then be characterized to determine if it operates over the range of voltage, frequency and temperature that is required. Using the characterization process described herein with time efficient crash detection may significantly speed up the characterization process.

Each of the prewritten test patterns for a particular SoC may be any kind of test pattern. The time efficient crash detection process described herein allows any test pattern to be uses as it is without doing any change, with no need to understand the details of the test pattern itself. Typically, the tests patterns used for a safe voltage region search have not been built specifically for this purpose; they come from specific tests such as DDR memory throughput performance, Video H.264 Encode 1080p, L1 cache memory stress, etc. They may be used “as it is” using the characterization process as described herein.

Detecting a crash using a simple dead man timer inside the test pattern would have numerous drawbacks: 1) to tune a timer would be time consuming as this would have to be done for each test pattern; 2) running the test pattern at different frequencies (i.e. different speeds) would also require further tuning of the timer for each frequency; and 3) for any (even minor) change inside the test pattern itself, the timer would need to be tuned again.

### Other Embodiments

While embodiments of the invention have been described with reference to illustrative embodiments, this description is not intended to be construed in a limiting sense. Various other embodiments of the invention will be apparent to persons skilled in the art upon reference to this description. For example, while characterization of a SoC was described, the principles disclosed herein may be applied to testing and characterization of many types of complex integrated circuits, and complex systems of circuit boards, personal computers, notebook computers, etc.

Although embodiments of the invention find particular application to a System on a Chip (SoC), it also finds application to other forms of integrated circuits. A SoC may contain one or more megacells or modules which each include custom designed functional circuits combined with pre-designed functional circuits provided by a design library.

While embodiments of the invention described herein test for a minimal safe operation voltage, other embodiments may check for a maximum or minimum safe operating frequency, a maximum or minimum safe operating temperature, a maximum or minimum safe pressure, etc.

While embodiments of the invention described herein analyzed a log file produced by a UART communication channel, other embodiments may use other forms of communication, such as a parallel channel, a wireless channel, etc. that are amenable to receiving status data from the system being tested and forming a log file of the received status data. Other embodiments may form a log file in a memory region within the system being tested that is accessible to the system monitor, for example.

The techniques described in this disclosure may be implemented in hardware, software, firmware, or any combination thereof. If implemented in software, the software may be executed in one or more processors, such as a microprocessor, application specific integrated circuit (ASIC), field programmable gate array (FPGA), or digital signal processor (DSP). The software that executes the techniques may be initially stored in a computer-readable medium such as compact disc (CD), a diskette, a tape, a file, memory, or any other computer readable storage device and loaded and executed in the processor. In some cases, the software may also be sold in a computer program product, which includes the computer-readable medium and packaging materials for the computer-readable medium. In some cases, the software instructions may be distributed via removable computer readable media (e.g., floppy disk, optical disk, flash memory, USB key), via a transmission path from computer readable media on another digital system, etc.

Certain terms are used throughout the description and the claims to refer to particular system components. As one skilled in the art will appreciate, components in digital systems may be referred to by different names and/or may be combined in ways not shown herein without departing from the described functionality. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” and derivatives thereof are intended to mean an indirect, direct, optical, and/or wireless electrical connection. Thus, if a first device couples to a second device, that connection may be through a direct electrical connection, through an indirect electrical connection via other devices and connections, through an optical electrical connection, and/or through a wireless electrical connection.

Although method steps may be presented and described herein in a sequential fashion, one or more of the steps shown and described may be omitted, repeated, performed concurrently, and/or performed in a different order than the order shown in the figures and/or described herein. Accordingly, embodiments of the invention should not be considered limited to the specific ordering of steps shown in the figures and/or described herein.

It is therefore contemplated that the appended claims will cover any such modifications of the embodiments as fall within the true scope and spirit of the invention.

What is claimed is:

1. A process of operating an integrated circuit test system, the test system including a host computer and a test platform coupled to the host computer, the test platform including a voltage source, a clock source, and a socket for coupling an integrated circuit to the host computer, the voltage source, and the clock source, the process comprising:
(a) coupling an integrated circuit having clock domains in the socket;
(b) selecting in the host computer a clock domain in the integrated circuit to be tested;
(c) downloading from the host computer to the test platform settings for the voltage source and the clock source;
(d) downloading from the host computer to the integrated circuit a test program;
(e) executing in the integrated circuit the test program, the executing including sending status information to a log file in the host computer;
(f) waiting a sleep time period for the integrated circuit to execute the test program;
(g) scanning the length of status information in the log file by the host computer;
(h) initiated a crash recovery process if the length of status information in the log file is greater than an empty log value and returning to the sleep time period if the length of status information in the log file is less than the empty log file;
(i) initiating a crash recovery process if the length of status information in the log file is equal to or greater than a limit value;
(j) initiating a crash recovery process if the status information in the log file contains a specific word; and
(k) initiating a crash recovery process if the length of status information in the log file exceeds a maximum freeze value and returning to the sleep time period if the length of status information in the log file is less than the maximum freeze value.

2. The process of claim 1 including iteratively changing the settings for the voltage source and the clock source until initiating a crash recovery process.

3. The process of claim 1 including iteratively changing the clock domain in the integrated circuit to be tested until initiating a crash recovery process.

4. The process of claim 1 including recording in the host computer the length of status information in the log file as safe settings for the voltage source and the clock source.

5. The process of claim 1 in which the initiating a crash recovery process includes rebooting the integrated circuit each time a crash is detected prior to executing a test program.

6. A test system comprising:
(a) a test platform having a socket for an integrated circuit with clock domains, a voltage source coupled to the socket, and a clock source coupled to the socket;
(b) a communications channel coupled to the socket, the voltage source, and the clock source;
(c) a host computer having a system monitor coupled to the communications channel, test programs coupled to the system monitor, and a log file coupled to the system monitor, the test programs operating the test system by:
(i) selecting in the host computer a clock domain in the integrated circuit to be tested;
(ii) downloading from the host computer to the test platform settings for the voltage source and the clock source;
(iii) downloading from the host computer to the integrated circuit a test program;
(iv) executing in the integrated circuit the test program, the executing including sending status information to a log file in the host computer;
(v) waiting a sleep time period for the integrated circuit to execute the test program;
(vi) scanning the length of status information in the log file by the host computer;
(vii) initiated a crash recovery process if the length of status information in the log file is greater than an empty log value and returning to the sleep time period if the length of status information in the log file is less than the empty log file;
(viii) initiating a crash recovery process if the length of status information in the log file is equal to or greater than a limit value;
(ix) initiating a crash recovery process if the status information in the log file contains a specific word; and
(x) initiating a crash recovery process if the length of status information in the log file exceeds a maximum freeze value and returning to the sleep time period if the length of status information in the log file is less than the maximum freeze value.

7. The system of claim 6 in which the test programs operate the system by iteratively changing the settings for the voltage source and the clock source until initiating a crash recovery process.

8. The system of claim 6 in which the test programs operate by iteratively changing the clock domain in the integrated circuit to be tested until initiating a crash recovery process.

9. The system of claim 6 in which the test programs operate by recording in the host monitor the length of status information in the log file as safe settings for the voltage source and the clock source.

10. The system of claim 6 in which the test programs operate by initiating a crash recovery process by rebooting the integrated circuit each time a crash is detected prior to executing a test program.
